(19) United States
(12) Patent Application Publication
(10) Pub. No.: US 2005/0189977 A1
(43) Pub. Date: Sep. 1, 2005

(54) Double-edge-trigger flip-flop

(76) Inventor: Chung-Hui Chen, Hsin Chu City (TW)

Correspondence Address: DUANE MORRIS, LLP;IP DEPARTMENT, ONE LIBERTY PLACE, PHILADELPHIA, PA, 19103-7396, US

(21) Appl. No.: 10/791,044

(22) Filed: Mar. 1, 2004

(51) Int. Cl. H03D 13/00

(52) U.S. Cl. 327/218

(57) ABSTRACT

A double-edge-trigger flip-flop comprising a first pass gate controlled by a clock signal and an inverted signal of the clock for passing an input; a second pass gate controlled by the clock signal and the inverted signal of the clock for passing the input in a complementary manner with regard to the first pass gate; a first signal passing module for further passing the input passed by the first pass gate into a third pass gate controlled by the clock signal and the inverted signal of the clock for generating a first part of an output of the flip-flop, wherein the third pass gate passes the input in a complementary manner with regard to the first pass gate; and a second signal passing module for further passing the input passed by the second pass gate into a fourth pass gate controlled by the clock signal and the inverted signal of the clock for generating a second part of the output, wherein the fourth pass gate passes the input in a complementary manner with regard to the second pass gate.

### BACKGROUND OF INVENTION

This invention generally relates to double-edge-trigger flip-flops, and more specifically, relates to fast double-edge-trigger flip-flops.

A flip-flop is an electronic circuit that stores a selected logical state in response to a clock pulse and one or more data input signals. Flip-flops are used in computational circuits. In these circuits, the flip-flops operate in selected sequences during recurring clock intervals to capture and hold certain data for a period of time sufficient for the other circuits within the system to further process that data. At each clock signal, data are stored in a set of flip-flops whose outputs are available to be applied as inputs to other combinatorial or sequential circuitry during successive clock signals. In this manner, sequential logic circuits are operated to capture, store and transfer data during the successive clock signals.

Most flip-flops are designed to store the logical state represented by an input signal present when a leading edge of a clock pulse is received. Other flip-flops store the logical state indicated by an input signal on receipt of the trailing edge of a clock pulse. Still other flip-flops store data on both the leading edge and the trailing edge of a clock pulse. These latter flip-flops are referred to as double-edge-trigger flip-flops.

Double-edge triggered flip-flops are commonly used in circuits where it is desirable to have a fast clock as well as a normal system clock. As it is also desirable to minimize clock distribution to save layout space, double edge triggered flip-flops offer an option of providing components operating at more than one speed of operation but which require only a single clock. Such techniques also have advantages in saving power, since it is only necessary to generate one source clock signal for two speeds of operation. In particular, since power consumption of the clock distribution network is proportional to the frequency of the clock, achieving a certain speed of operation using a half-speed clock source will reduce the power consumption of the clock network by half, when compared to single edge flip-flop operation. With system speeds approaching 100 GHz, the double-edge-trigger logical flip-flop design is required to lower the clock speed to approximately half the speed of conventional flip-flops.

Most common high-speed double-edge-trigger flip-flops are formed by two flip-flops, one is positive or rising edge triggered and another is negative triggered or falling edge triggered. A rising edge triggered flip-flop is a device that latches and holds the logic state of its data input signal when the rising edge of its clock input signal is detected. Similarly, a falling edge triggered flip-flop is a device that latches and holds the logic state of its data input signal when the falling edge of its clock input signal is detected.

Therefore, a double edge triggered flip-flop is a device that latches and holds the logic state of its data input signal when the rising edge or the falling edge of its clock input signal is detected. Double-edge triggered flip-flops are commonly used in double data rate Random Access Memories (RAMs) and in high speed bus interfaces.

Since a typical flip-flop is always made from a cross coupled inverter, which is slow, edge triggering frequently causes data delays. True single phased designs (TSPC), such as the double-edge-trigger flip-flops, always cascade three or four Metal Oxide Semiconductor Field Effect Transistors (MOSFETs) from power to ground in its circuit, which also leads to slower performance.

Desirable in the art of double-edge-trigger flip-flop design are additional designs that eliminate the use of regular flip-flops, which require cross couple inverters, thereby not only shorting the data path but reducing data delays due to slow edge triggering.

### SUMMARY

In view of the foregoing, this disclosure provides a fast double-edge-trigger flip-flop and the method for operating the same.

In one example, the circuit comprises a first pass gate having one end connectable to an incoming data node and the other end connectable to a first signal passing module such as a NAND gate; a second pass gate having one end connectable to an incoming data node and the other end connectable to a second signal passing module; a third pass gate with one end connectable to the output of the first signal passing module and the other end connectable to a driver module; and a fourth pass gate with one end connectable to the output of the second signal passing module and the other end connectable to the driver module, whose output is the desired output of the double-edge trigger flip-flop.

In another example, a flag signal is added to be connectable as inputs to the first and second signal passing modules, wherein the flag identifies the power status of the circuit to prevent leakage problems when the flip-flop is not in operation.

Various benefits and aspects of the present disclosure will be clearer with the detailed explanation below.

### BRIEF DESCRIPTION OF THE DRAWINGS

FIG. 1 illustrates a conventional double-edge triggered flip-flop.

FIG. 2 illustrates a timing diagram during the operation of the conventional doubled-edge triggered flip-flop.

FIG. 3 illustrates a fast double-edge-trigger flip-flop in accordance with one example of the present disclosure.

FIG. 4 illustrates a timing diagram during the operation of the fast double-edge-trigger flip-flop in accordance with one example of the present disclosure.

### DESCRIPTION

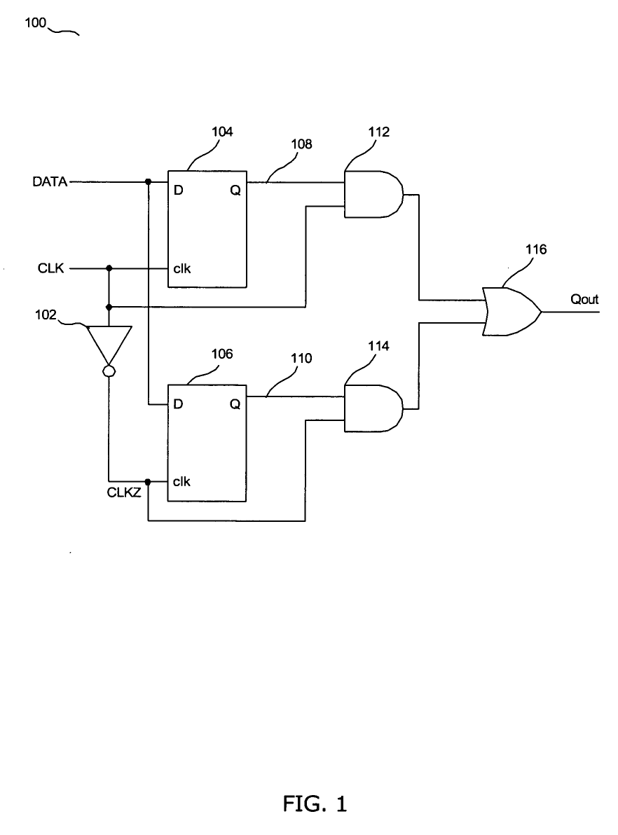

FIG. 1 shows a circuit diagram illustrating a conventional double edge triggered flip-flop 100. As shown in FIG. 1, the flop-flop 100 includes a clock inverter 102 whose input is connected to an external clock signal CLK. The output of clock inverter 102 generates an inverted clock signal CLKZ.

Flip-flop 100 also includes two D flip-flops 104 and 106. Flip-flop 104, which is clocked to CLK, has a data input that is connected to an external data input DATA. Furthermore, flip-flop 104 also generates an output signal 108.

Similarly, flip-flop 106, which is clocked to CLKZ, has a data input that is connected to DATA. Furthermore, flip-flop 106 also generates an output signal 110.

As further shown in FIG. 1, flip-flop 100 also includes a pair of 2-input AND gates 112 and 114, and a 2-input OR gate 116. AND gate 112 has output signal 108 and CLK as its inputs, while AND gate 114 has output signal 110 and CLKZ as inputs. OR gate 116 has a first input connected to the output of AND gate 112 and a second input connected to the output of AND gate 114, and produces an output signal Qout.

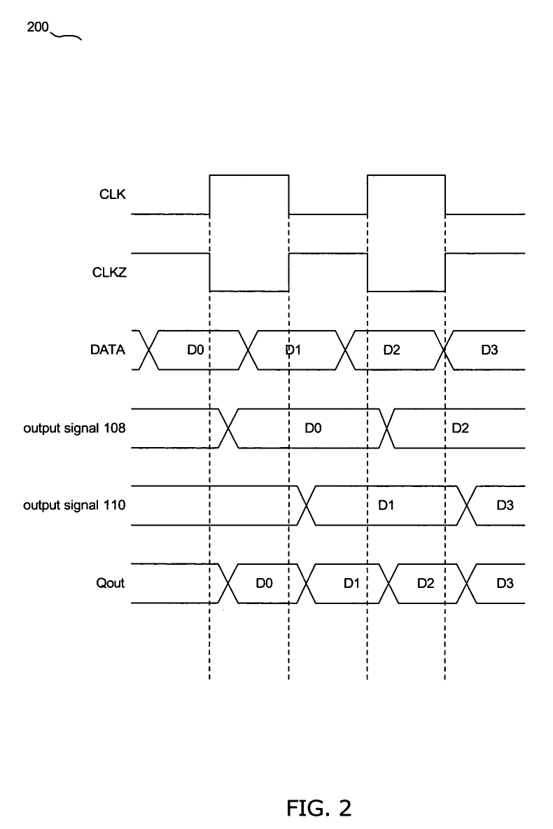

FIG. 2 illustrates a timing diagram demonstrating the operation of flip-flop 100. As shown in FIGS. 1 and 2, the rising edge of CLK causes flip-flop 104 to latch the logic state of the data input signal DATA. When latched, output signal 108 carries DATA (D0 and D2). Since CLK is high, AND gate 112 passes output signal 108 to OR gate 116, which produces that DATA (D0 and D2) at Qout. At the same time, since CLKZ is low, AND gate 114 does not pass any data to OR gate 116.

Similarly, the falling edge of CLK causes flip-flop 106 to latch the logic state of the data input signal DATA. When latched, output signal 108 carries DATA (D1 and D3). Since CLKZ is now high, AND gate 114 passes output signal 108 to OR gate 116, which produces that DATA (D1 and D3) at Qout. At the same time, since CLK is low, AND gate 112 does not pass any data to OR gate 116. As such, DATA is passed to Qout whenever there is a rising or a falling edge.

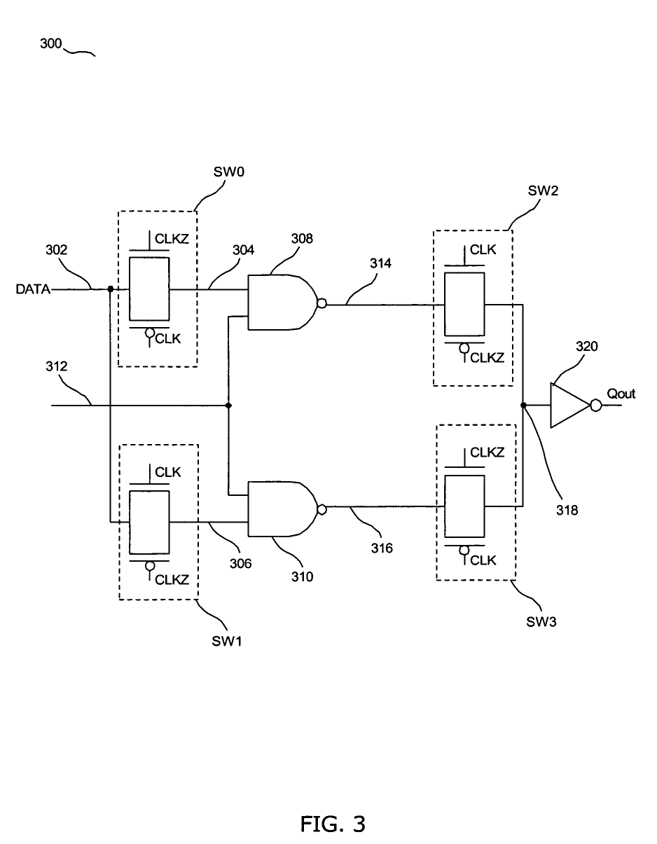

FIG. 3 shows a circuit diagram illustrating a fast double-edge-trigger flip-flop 300 in accordance with the present disclosure. It includes a pass gate SW0 whose input node 302 is connected to an external data input DATA. The output of pass gate SW0 generates a data signal 304. The PMOS of pass gate SW0 is connected to a clock input CLK, while the NMOS of pass gate SW0 is connected to the inverse of the clock input CLK, or CLKZ. In other words, the pass gate SW0 operates as an on/off switch. In the example shown, the pass gates can be constructed by connecting a PMOS and NMOS device in parallel with their gates being controlled by the clock input.

Also shown in FIG. 3, flip-flop 300 includes a pass gate SW1 whose input 302 is connected to the external data input DATA. The output of pass gate SW1 generates a data signal 306. The NMOS of pass gate SW1 is connected to CLK, while the PMOS of pass gate SW1 is connected to CLKZ. In other words, the pass gate SW1 operates as an on/off switch. It is noticed that pass gate SW0 and SW1 operate in a complementary manner with regard to each other. That is, when the clock input is low, SW0 is operating to pass the input DATA through when at the same time SW1 is turned off. Similarly, when SW1 is operating, SW0 is not.

Flip-flop 300 also includes two two-input NAND gates 308 and 310. NAND gate 308 has the data signal 304 and a flag signal 312 as its two inputs, while NAND gate 310 has the data signal 306 and the flag signal 312 as its two inputs. Furthermore, NAND gate 308 has an output signal 314, while NAND gate 310 has an output signal 316.

The outputs of NAND gates 308 and 310 are connected to pass gates SW2 and SW3, respectively. The output signals of pass gates SW2 and SW3 are further fed, as an input signal 318, to an inverter 320, which has an output Qout, which is also the output of flip-flop 300. The NMOS of pass gate SW2 is connected to CLK, while the PMOS of pass gate SW2 is connected to CLKZ. The PMOS of pass gate SW3 is connected to CLK, while the NMOS of pass gate SW3 is connected to CLKZ. In other words, both pass gates SW2 and SW3 operate as on/off switches. It is further noted that SW2 operates in a complementary manner with regard to SW0 based on the clock input as well. Similarly, SW3 operates in a complementary manner with regard to SW1 based on the clock input.

Flag signal 312 acts as a switch to prevent leakage. During normal flip-flop operations, flag signal 312 is set to a “1” so that the flip-flop can pass the input with disturbance. When flip-flop operations are no longer necessary, to avoid leakage, flag signal 312 is set to a “0”, thereby pulling both output signals 314 and 316 to a “1” to discontinue the operation of the flip-flop 300. Then, as long as either SW2 or SW3 is on, the input signal 318 is always a “1”, while Qout, which is the inverse of the input signal 318, is always a “0”, thereby avoiding leakage. It is however understood by those skilled in the art that if the flip-flop 300 does not have to be powered down, or if the leakage is not a design concern, both NAND gates 308 and 310 can be replaced by a driver module such as an inverter for passing the input signal.

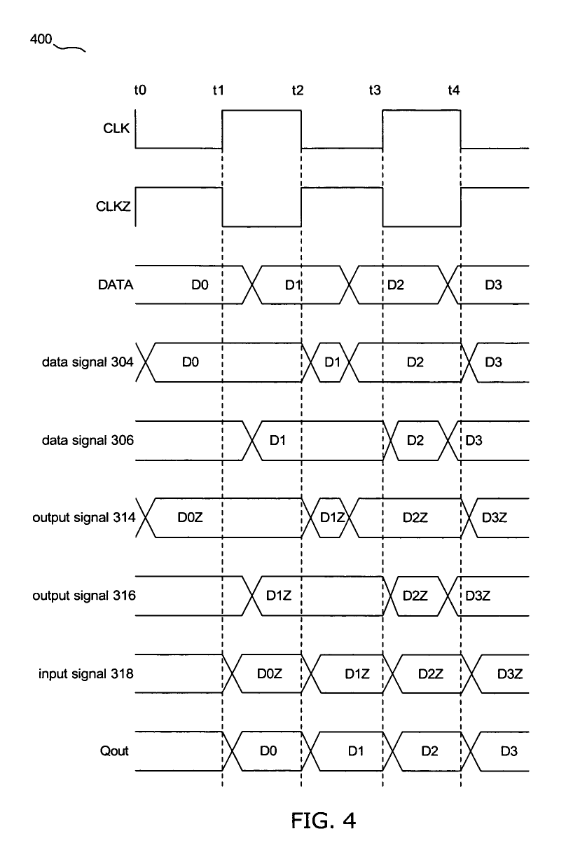

FIG. 4 illustrates a timing diagram when CLK and CLKZ are propagating. With reference to both FIGS. 3 and 4, the boundaries of the clock periods are artificially marked by “t1-t4” for illustration purposes. When between t0 and t1, CLK is set to a logical zero and CLKZ to a logical one. During this period, both SW1 and SW2 are turned off, while both SW0 and SW3 are turned on. As a result, data signal 304 carries DATA (D0), while output signal 314 carries the passed the inverted DATA (D0Z) since it is a NAND gate 308 situated between these two nodes. When CLK finally rises at t1, SW2 is turned on, thereby passing D0Z from output signal 314 to input signal 318 and further inverted to set DATA (D0) at Qout.

When between t1 and t2, CLK is set to a logical one and CLKZ to a logical zero. During this period, both SW0 and SW3 are turned off, while both SW1 and SW2 are turned on. As a result, SW1 is passing the input DATA (D0 and D1) to signal 306 and further to output signal 316 through the NAND gate 310, but not any further. Since SW3 is turned off, output signal 316 is not passed to input signal 318 and Qout is supplied by the output from SW2. When CLK falls at t2, SW3 is turned on, thereby passing the latched data DATA (D1Z) from output signal 316 to input signal 318 and setting DATA (D1) at Qout.

After the falling edge at t0 and during the period between t0 and t2, SW0 does not pass any more new input until another falling edge at t2. As such, the signals 304 and 314 carry DATA (D0 and D0Z), and the NAND gate 308 can be viewed as a device storing the input.

Between t2 and t3, CLK is set to a logical zero and CLKZ to a logical one. During this period, both SW1 and SW2 are turned off, while both SW0 and SW3 are turned on. As a result, data signal 304 carries new DATA (D1 and D2), while output signal 314 carries the inverted DATA (D1Z and D2Z). The output signal 316 passes the DATA (D1Z) that is stored at the NAND gate 308 through SW3 to input signal 318. Through the inverter 320, Qout now carries DATA (D1).

Similar to SW0, After the rising edge at t1 and during the period between t1 and t3, SW1 does not pass any more new input until another rising edge at t3. As such, the signals 306 and 316 carry DATA (D1 and D1Z), and the NAND gate 310 can be viewed as a device storing the input.

When CLK finally rises at t3 and fall at t4, similar propagation is happening as described above. In essence, SW0 and SW1 receive the input data in a complementary manner with regard to each other based on a clock input, and so do SW2 and SW3. Furthermore, SW0 and SW2 pass data in a complementary manner as well based on the same clock input. As a result, Qout produces new output data at both the rising and falling edges of the clock input.

The design simplifies the double-edge-trigger flip-flop by using pass gates and simple elements such as NAND gates and inverters. As it is well understood by designers in the field, the inverters and the pass gates all can be constructed with only two CMOS transistors. This design of a flip-flop speeds up the operation thereof and can be used high-speed standard cells, high-speed serial link systems (such as PCI Express, SATA, OC-768 and OC-192) and tera- or giga-hertz circuits that need double-edge-trigger cells to slow down the clock speeds.

The above disclosure provides many different embodiments, or examples, for implementing different features of the disclosure. Specific examples of components, and processes are described to help clarify the disclosure. These are, of course, merely examples and are not intended to limit the disclosure from that described in the claims.

Although illustrative embodiments of the disclosure have been shown and described, other modifications, changes, and substitutions are intended in the foregoing disclosure. Accordingly, it is appropriate that the appended claims be construed broadly and in a manner consistent with the scope of the disclosure, as set forth in the following claims.

1. A double-edge-trigger flip-flop comprising:
a first pass gate controlled by a clock signal and an inverted signal of the clock for passing an input;
a second pass gate controlled by the clock signal and the inverted signal of the clock for passing the input in a complementary manner with regard to the first pass gate;
a first signal passing module for further passing the input passed by the first pass gate into a third pass gate controlled by the clock signal and the inverted signal of the clock for generating a first part of an output of the flip-flop, wherein the third pass gate passes the input in a complementary manner with regard to the first pass gate; and
a second signal passing module for further passing the input passed by the second pass gate into a fourth pass gate controlled by the clock signal and the inverted signal of the clock for generating a second part of the output, wherein the fourth pass gate passes the input in a complementary manner with regard to the second pass gate.

2. The flip-flop of claim 1 further comprising a driver module passing the first part of the output on a first edge of the clock input and passing the second part of the output on a second edge of the clock input.

3. The flip-flop of claim 1 wherein the first signal passing module and the second signal passing module are inverters.

4. The flip-flop of claim 1 wherein the first signal passing module and the second signal passing module are NAND gates receiving a flag signal together with the passed input wherein the flag signal disenables the flip-flop when it is asserted.

5. The flip-flop of claim 1 wherein the first and fourth pass gates have a PMOS and an NMOS transistor connected in parallel for passing the input with the PMOS transistors thereof controlled by the clock input and the NMOS transistors thereof controlled by the inverted signal of the clock input.

6. The flip-flop of claim 1 wherein the second and third pass gates have a PMOS and an NMOS transistors connected in parallel for passing the input with the NMOS transistors thereof controlled by the clock input and the PMOS transistors thereof controlled by the inverted signal of the clock input.

7. A double-edge-trigger flip-flop comprising:
a first pass gate passing an input when a clock input having a low value;
a second pass gate passing the input when the clock input having a high value;
a first signal passing module for further passing the input passed by the first pass gate into a third pass gate which passes the input when the clock has a high value to generate a first output;
a second signal passing module for further passing the input passed by the second gate into a fourth pass gate which passes the input when the clock has a low value to generate a second output; and
a driver module passing the first output as an output of the flip-flop on the rising edge of the clock input and passing the second output as the output of the flip-flop on the falling edge of the clock input.

8. The flip-flop of claim 7 wherein the first signal passing module and the second signal passing module are inverters.

9. The flip-flop of claim 7 wherein the first signal passing module and the second signal passing module are NAND gates receiving a flag signal together with the passed input wherein the flag signal disenables the flip-flop when it is asserted.

10. The flip-flop of claim 7 wherein the first and fourth pass gates have a PMOS and an NMOS transistor connected in parallel for passing the input with the PMOS transistors thereof controlled by the clock input and the NMOS transistors thereof controlled by an inverted signal of the clock input.

11. The flip-flop of claim 7 wherein the second and third pass gates have a PMOS and an NMOS transistors connected in parallel for passing the input with the NMOS transistors thereof controlled by the clock input and the PMOS transistors thereof controlled by an inverted signal of the clock input.

12. A double-edge-trigger flip-flop comprising:
a first pass gate controlled by a clock signal and an inverted signal of the clock for passing an input;
a second pass gate controlled by the clock signal and the inverted signal of the clock for passing the input in a complementary manner with regard to the first pass gate;
a first signal passing module for further passing the input passed by the first pass gate into a third pass gate controlled by the clock signal and the inverted signal of the clock for generating a first part of an output of the flip-flop, wherein the third pass gate passes the input in a complementary manner with regard to the first pass gate;
a second signal passing module for further passing the input passed by the second pass gate into a fourth pass gate controlled by the clock signal and the inverted signal of the clock for generating a second part of the output, wherein the fourth pass gate passes the input in a complementary manner with regard to the second pass gate; and
a driver module passing the first part of the output on a first edge of the clock input and passing the second part of the output on a second edge of the clock input,
wherein the first and fourth pass gates have a PMOS and an NMOS transistor connected in parallel for passing the input with the PMOS transistors thereof controlled by the clock input and the NMOS transistors thereof controlled by the inverted signal of the clock input, and
wherein the second and third pass gates have a PMOS and an NMOS transistors connected in parallel for passing the input with the NMOS transistors thereof controlled by the clock input and the PMOS transistors thereof controlled by the inverted signal of the clock input.

13. The flip-flop of claim 12 wherein the first signal passing module and the second signal passing module are inverters.

14. The flip-flop of claim 12 wherein the first signal passing module and the second signal passing module are NAND gates receiving a flag signal together with the passed input.

15. A method for passing an input through a double-edge-trigger flip-flop, the method comprising:
passing an input through a first pass gate controlled by a clock signal and an inverted signal of the clock;
passing the input through a second pass gate controlled by the clock signal and the inverted signal of the clock in a complementary manner with regard to the first pass gate;
passing the input passed by the first pass gate through a first signal passing module;
passing the input passed by the first signal passing module to a third pass gate controlled by the clock signal and the inverted signal of the clock for generating a first part of an output of the flip-flop, wherein the third pass gate passes the input in a complementary manner with regard to the first pass gate;
passing the input passed by the second pass gate through a second signal passing module;
passing the input passed by the second signal passing module to a fourth pass gate controlled by the clock signal and the inverted signal of the clock for generating a second part of the output, wherein the fourth pass gate passes the input in a complementary manner with regard to the second pass gate,
wherein the first and second parts of the output are produced upon two edges of the clock signal sequentially.

16. The method of claim 15 further comprising passing the first and second parts of the output through a driver module.

17. The method of claim 16 wherein the driver module is an inverter.

18. The method of claim 15 wherein the first signal passing module and the second signal passing module are inverters.

19. The method of claim 15 wherein the first signal passing module and the second signal passing module are NAND gates receiving a flag signal together with the passed input wherein when the flag signal disenables the flip-flop when it is asserted.

20. The method of claim 15 wherein the first and fourth pass gates have a PMOS and an NMOS transistor connected in parallel for passing the input with the PMOS transistors thereof controlled by the clock input and the NMOS transistors thereof controlled by the inverted signal of the clock input, and wherein the second and third pass gates have a PMOS and an NMOS transistors connected in parallel for passing the input with the NMOS transistors thereof controlled by the clock input and the PMOS transistors thereof controlled by the inverted signal of the clock input.
